(19) United States
(12) Patent Application Publication
(10) Pub. No.: US 2010/0006827 A1
(43) Pub. Date: Jan. 14, 2010

(54) Electroluminescent Device

(75) Inventor: Alastair Robert Buckley, Sheffield (GB)

Correspondence Address: HOWSON & HOWSON LLP, 501 OFFICE CENTER DRIVE, SUITE 210, FORT WASHINGTON, PA, 19034, US

(73) Assignee: MICROEMISSIVE DISPLAYS LIMITED, Edinburgh (GB)

(21) Appl. No.: 12/282,418

(22) PCT Filed: Mar. 12, 2007
(86) PCT No.: PCT/GB2007/000858

§ 371 Date: May 21, 2009

(30) Foreign Application Priority Data
Mar. 13, 2006 (GB) 0605014.0

(51) Int. Cl. H01L 51/54; H01L 51/56

(52) U.S. Cl. 257/40; 438/26; 257/E51.027; 257/E21.502

(57) ABSTRACT

An electroluminescent device comprises, in order: an opaque semiconducting substrate (1) including active circuitry (2); an anode (3); a layer of oxide material (4); a hole transport layer (5); a layer of light-emitting polymer (6); a transparent cathode (7); and an encapsulation (8). The oxide material (4) may in particular comprise a transition metal oxide. A method of forming the device is also disclosed.

### BACKGROUND TO THE INVENTION

This invention relates to an electroluminescent device including polymer organic electroluminescent material.

Organic light emitting diodes (OLEDs) have been divided into two categories from the very start of their development. The SM-OLED (small molecule organic light emitting diode) is starkly differentiated from the P-OLED (polymer OLED) in both material and manufacturing technique. Polymer OLEDs are described in U.S. Pat. No. 5,247,190.

OLED displays have historically been developed on ITO (indium tin oxide) substrates that have the advantage of being both transparent and conducting and also widely manufactured in the field of LCD displays. The ITO substrate is both an effective way of creating a passive matrix display backplane (for small area low resolution displays) and an anode for injecting holes into the OLED device. This is true for both P-OLED and SM-OLED technologies. (In comparison to LCD displays: the requirement for hole injection from the ITO is removed as an LCD display is a voltage driven device). An OLED must have at least one transparent electrode and must have efficient hole injection. ITO has been used as a substrate for OLED technology development because it exists (for the manufacture of LCD displays) and because it fulfils the two basic requirements of transparency and hole injection ability. The counter electrode in an OLED display is almost always vacuum evaporated on top of the organic layers. This counter electrode is normally the cathode of the device providing an efficient source of electrons.

Improvements in display technology have often been achieved when transparent ITO substrates have been replaced by non-transparent silicon based substrates capable of creating high-resolution active matrix display circuitry. We have taken this technological step and have manufactured P-OLED microdisplays based on CMOS silicon backplanes. These displays must be transparent from the cathode side. It therefore makes no manufacturing or commercial sense for the anode of such a P-OLED microdisplay to be made of ITO.

We have used an anode comprised of two layers. The first is titanium metal that forms the top layer of the CMOS wafer as delivered from the semiconductor foundry. The second layer is PEDOT:PSS (Polyethylene di-oxythiophene polystyrene sulphonate). The original patent describing the incorporation of PEDOT:PSS into P-OLED devices is U.S. Pat. No. 6,551,727. There are a number of disadvantages to this anode system which will now be discussed. The first disadvantage is that PEDOT:PSS is intrinsically conducting resulting in pixel cross talk which is not desirable. (Depending on the drive scheme of the display, voltage drive or current drive, the intrinsic conductivity of the PEDOT:PSS results in a power loss, or a loss of colour saturation respectively.) The second disadvantage is that the PEDOT:PSS also acts as a solid state electrolyte (due to the manufacturing process of the PEDOT:PSS). This means that ions in the PEDOT:PSS layer can migrate laterally in the film under the influence of a lateral electric field as found when neighbouring pixels are on and off respectively. The migration of ions modifies the conductivity and hole injection properties of the PEDOT:PSS and creates image artefacts in the display. This property of PEDOT:PSS is very undesirable and is present not only in microdisplays but in all passive and active matrix pixel displays using PEDOT:PSS. This problem is recognised in WO 2004/105150 and in de Kok et al, Phys. Stat. Sol. (a) 201, No 6, 1342-1359 (2004).

The third issue with the use of PEDOT:PSS is that it is considered, by those skilled in the art, to limit the intrinsic performance of P-OLED devices in terms of lifetime. There are a number of publications regarding the non-linear conductivity of PEDOT:PSS in a number of different experimental environments: Kvarnstrom et al, J. Mol. Structure 521 (2000) 271-277; Taylor et al, App. Phys. Lett. 85 (2004) 23; Moller et al, J. App. Phys. 94 (2003) 12.

Thus, finding an alternative material to replace PEDOT:PSS would enable faster progression of the technology.

PEDOT:PSS is traditionally used in P-OLED devices for two reasons:

ITO anodes are intrinsically unstable and they need conditioning with an oxygen plasma before an efficient hole injecting surface is fabricated. The process of the oxygen plasma is not well understood but is applied in all commercial fabrications whether making P-OLED or SM-OLED devices. In P-OLED devices PEDOT:PSS was found to reduce the variability of the plasma treated hole injecting surface and provide an improvement in reliability and hole injection efficiency over the bare ITO substrate.

The other issue with ITO is that it is quite a rough surface with defects occurring regularly over a substrate. Because these defects are conducting with spike type profiles very large electric fields result in their vicinity. The chance of a short circuit between the anode and cathode is very high when a P-OLED device is fabricated without PEDOT:PSS. When PEDOT:PSS is introduced at a thickness in the order of the ITO film thickness (several hundred nanometers) the chance of a short circuit occurring is reduced by many orders of magnitude.

PEDOT:PSS is known as a Hole injection layer (HIL) in OLED technology.

In comparison, SM-OLED displays do not typically utilise PEDOT:PSS to reduce the chance of short circuit for two reasons. Firstly, SM-OLED materials are typically of higher density than P-OLED materials due to the nature of their deposition. This will intrinsically give the film more protection from short circuits. Secondly alternative HIL layers exist for SM-OLED devices that can perform the same function.

ITO is known not to be the best hole injection layer for both P-OLED and SM-OLED devices. Many publications show improvements in hole injection when utilising a range of inorganic and organic materials. These publications typically compare ITO and the new material and not ITO/PEDOT:PSS and the new material.

The materials include organic Self Assembled Monolayers (SAM) on ITO: Khodabakhsh et al, Adv. Funct. Mat. (2004) 14, No 12; MoOx, VOx, RuOx: Tokito et al, J. Phys. D: App. Phys. 29 (1996) 2750-2753; MoS₂+MoO₃: Reynolds et al, J. App. Phys. 92, 12, (2002); Pr₂O₃: Qui et al, IEEE Trans. Elec. Dev. 51, 7, (2004).

The oxide materials listed in 0014 are also cited in US-A-2005/0170208 which details an OLED device structure with a large number of the same benefits by utilising transition metal oxides and organic buffer layers as a hole injecting system for P-OLED devices.

A hole transport layer [HTL] is often used to improve the charge balance in SM-OLED devices by blocking electrons at the HTL/emitting layer interface.

In P-OLED technology the use of multiple layer devices where functionality is divided between hole transport, electron transport and light emission has been limited due to the material processing techniques. Typically P-OLED materials are processed from aromatic solutions. It has not been possible to layer different materials with different functionalities because the solvent systems for the different materials are typically the same and the first layer would dissolve as the second was coated. This problem does not exist for SM-OLED technology as the materials are vacuum evaporated directly one on top of the other.

### SUMMARY OF THE INVENTION

We have discovered that the hole injecting properties of the oxide materials cited in the above listed publications can be used in novel devices with an enhanced effect.

The invention provides an electroluminescent device comprising, in order: an opaque semiconducting substrate including active circuitry; an anode; a layer of oxide material; a hole transport layer; a layer of light emitting polymer; a transparent cathode; and an encapsulation.

The circuitry may comprise CMOS (complementary metal oxide semiconductor) circuitry. If so, the anode may comprise aluminium, but it may alternatively comprise titanium or another metal or alloy.

The oxide material may be a metal oxide and may be a semiconducting oxide material. It may be selected from transition metal oxides comprising oxides of vanadium (V), molybdenum (Mo), tungsten (W), chromium (Cr), zirconium, (Zr), copper (Cu), nickel (Ni), ruthenium (Ru) etc . . . Alternatively it may comprise an oxide of aluminum (Al), indium (In), gallium (Ga), tin (Sn), etc or a rare earth element including lanthanoids or actinoids. Mixtures of these oxides can also be used. We have found it advantageous if this layer is from 1 to 15 nm thick, in particular about 5 nm.

The hole transport layer may in particular comprise a cross linkable version of TFB (Poly[(9,9-dioctylfluorenyl-2,7-diyl)-co-(4,4′-(N-(4-sec-butylphenyl))diphenylamine)] or any high-hole-mobility organic material that can be rendered insoluble to aromatic solvents once coated.

The light-emitting polymer may comprise a material sold under the registered trade mark Lumation by Sumitomo Chemical Co., Ltd.

The invention also provides a method of forming an electroluminescent device, comprising the steps of:
a. Providing a semiconducting substrate having a metal anode;
b. Depositing a thermodynamically stable oxide material on the anode;
c. Coating the oxide with a conjugated polymer hole transport layer;
d. Cross linking said hole transport layer;
e. Coating the hole transport layer with a layer of light-emitting polymer;
f. Coating a cathode on the light-emitting polymer; and
g. Encapsulating the device.

After step (a) the anode may be cleaned to remove native oxide.

After step (b) the oxide material may be annealed or exposed to plasma.

### BRIEF DESCRIPTION OF THE DRAWINGS

The invention will now be described in more detail, by way of example only, with reference to the accompanying drawings, in which:

FIG. 1 is a schematic cross-sectional view of a device according to an embodiment of the invention;

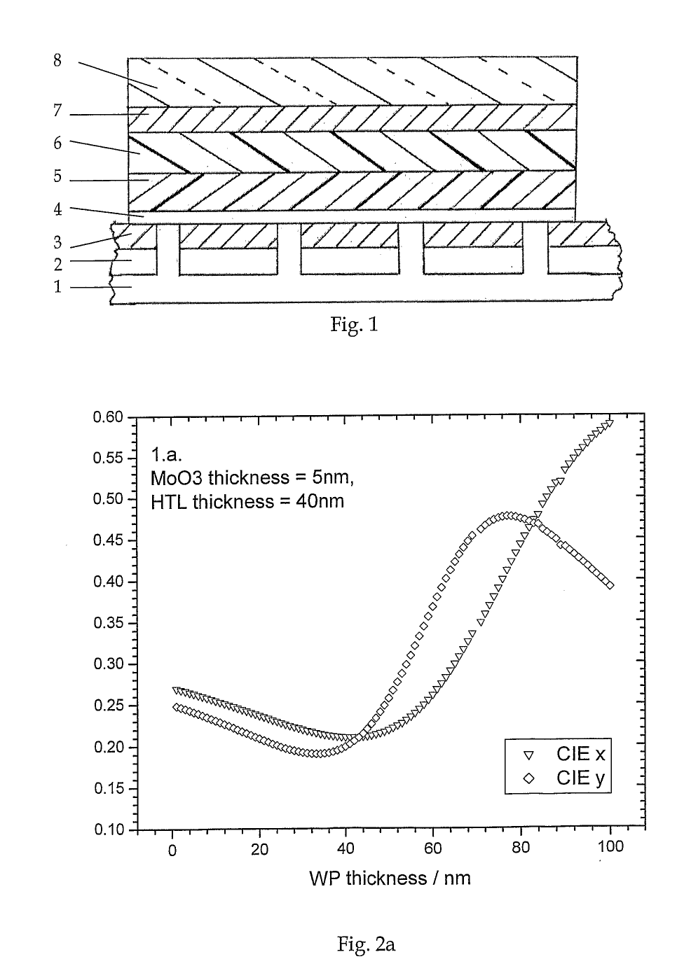

FIGS. 2a and 2b are graphs plotting CIE1931 coordinate values against light-emitting polymer later thickness for hole transport layer thicknesses of 40 nm and 10 nm respectively; and

FIG. 3 is a contour plot of light extraction as these two thicknesses are varied.

### DETAILED DESCRIPTION OF A PARTICULAR EMBODIMENT

The drawing shows an electroluminescent device comprising a semiconducting substrate 1 with integrated drive circuitry 2. Metal anodes 3, for example of aluminium (if the circuitry 2 is standard CMOS) or titanium, are formed on this circuitry.

After cleaning the anodes to remove native oxide, a thermodynamically stable transition metal oxide layer 4, having a thickness of about 5 nm, is deposited. This layer has a high work function, a low conductivity and forms a smooth controlled coating. For example, V₂O₅ and MoO₃ are suitable.

Optionally, the surface of the metal oxide layer 4 may be annealed or exposed to plasma exposure for even greater stability.

Next, a suitable thickness, e.g. about 40 nm, of a conjugated polymer hole transport layer 5 (e.g. cross-linkable TFB) is coated onto the metal oxide layer. Thermally activated cross-linking of the hole transport layer then takes place.

A required thickness (e.g. about 70 nm) of an active emitting layer 6 is then coated. This layer comprises a light-emitting polymer such as Lumation White. Subsequently, remaining device layers including a transparent cathode 7 and encapsulation 8 are coated.

The total thickness of the device is designed precisely for five reasons.

Firstly, thicker devices require higher voltages to achieve similar luminance's. Thinner devices allow more current to flow and more light to be generated for a particular operating voltage. For CMOS typically a maximum voltage of 6.5V is available.

Secondly, the tunability of the thickness of hole transporting and light emitting materials enables the balance of charge in the exciton recombination zone of the device to be optimised. Optimisation is a function of minimising exciton quenching at conducting electrodes and minimising transient unipolar currents. At least a minimum HTL thickness of 10 nm is required.

Thirdly, although the amount of current flowing in the device determines the amount of light that is generated and is maximised for thin devices, the amount of light that is extracted is a function of the optical system and the peak light extraction is typically at a total film thickness (i.e. the total thickness of the layers 4, 5, 6 between the electrodes 3, 7 and not including the electrodes) of about 100 nm if the recombination is in the centre of the film stack.

Fourthly, for different device structures there is typically a total film thickness that is required to minimise the risk of short circuit. For P-OLED on CMOS this is in the order of 90-120 nm.

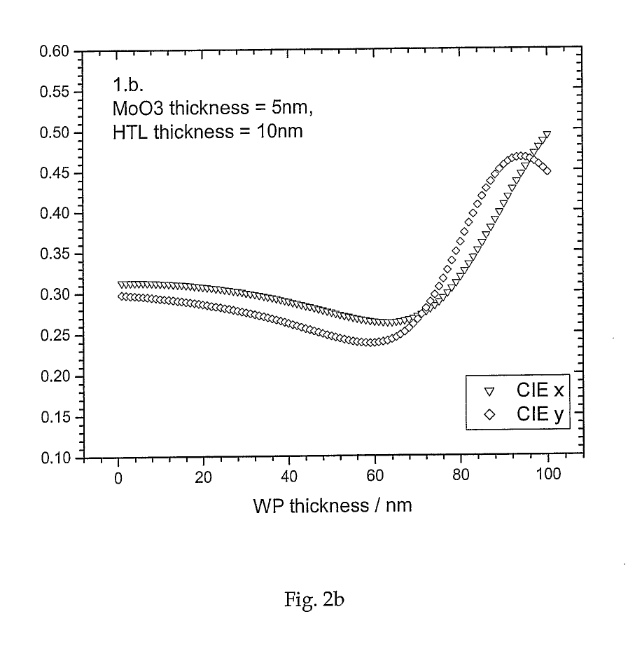

Fifthly, the colour of the device alters with thickness of the constituent polymer layers. When fabricating a microdisplay white light emission is required as defined by the CIE1931 colour analysis and is represented by coordinates x and y. A “good” white point is defined by CIE(x,y) of between (0.28,0.28) and (0.35,0.35). In FIG. 2a, the range of CIE(x,y) coordinates available for a representative variation of film thickness from 0 to 100 nm for a HTL layer thickness of 10 nm and 40 nm is shown.

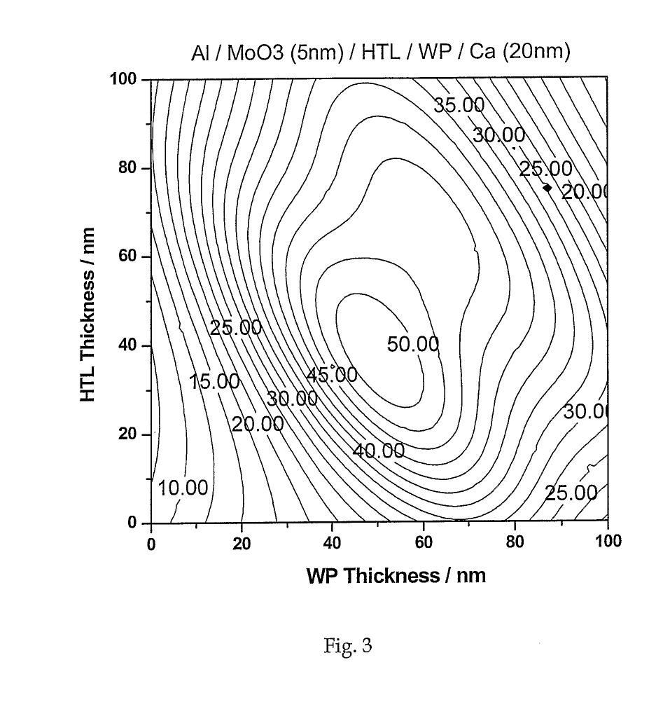

The range of HTL and light-emitting polymer layer thicknesses that provide satisfactory performance for the criteria listed paragraphs 0035 to 0039 above are shown for the case of the optimisation of light extraction in FIG. 3. A HTL thickness of between 20 nm and 50 nm, and a WP (white-light-emitting polymer) thickness of between 40 nm and 80 nm provide a regime of optimal light extraction. Within this regime it is then possible to optimise the other display performance parameters: colour, operating voltage, short circuit reliability, and charge balance.

It is important to be able to engineer the stack thickness to optimise for the above responses. Traditionally the optimisation was done using the PEDOT:PSS layer as the solvent system for PEDOT:PSS is water and orthogonal to the aromatic solvents of the semiconducting polymer layers that follow.

In the invention, PEDOT:PSS is replaced by the oxide/conjugated hole transport layers 4/5. The requirement for thickness tunability needs to be retained and in the invention the cross linkable TFB hole transport layer 5 is used to achieve this.

The benefits of the invention can be applied to all P-OLED displays, in particular P-OLED microdisplays.

The invention provides a “top emitting” device structure with transparent cathode 7. Due to the thin oxide layer 4 intrinsic cross talk is very low. There is little or no lateral ion migration.

1. An electroluminescent device comprising, in order: an opaque semiconducting substrate including active circuitry; an anode; a layer of oxide material; a hole transport layer; a layer of light-emitting polymer; a transparent cathode; and an encapsulation.

2. A device according to claim 1, wherein the circuitry comprises CMOS (complementary metal oxide semiconductor) circuitry.

3. A device according to claim 1, wherein the anode comprises aluminum.

4. A device according to claim 1, wherein the anode comprises titanium.

5. A device according to claim 1, wherein the oxide material comprises a metal oxide.

6. A device according to claim 1, wherein the oxide material comprises a transition metal oxide.

7. A device according to claim 6, wherein the oxide material is selected from oxides of vanadium (V), molybdenum (Mo), tungsten (W), chromium (Cr), zirconium (Zr), copper (Cu), nickel (Ni) and ruthenium (Ru).

8. A device according to claim 5, wherein the oxide material is selected from oxides of aluminum (Al), indium (In), gallium (Ga), tin (Sn), lead (Pb), or of lanthanoids or actinoids.

9. A device according to claim 1, wherein the oxide material is a mixture of oxides.

10. A device according to claim 1, wherein the oxide material is semiconducting.

11. A device according to claim 1, wherein the layer of oxide material is from 1 to 15 nm thick.

12. A device according to claim 1, wherein the hole transport layer comprises a high-hole-mobility organic material that can be rendered insoluble into aromatic solvents once coated.

13. A device according to claim 12, wherein the hole transport layer comprises a cross linkable version of TFB (Poly[(9,9-dioctylfluorenyl-2,7-diyl)-co-(4,4′-(N-(4-sec-butylphenyl))diphenylamine)].

14. A device according to claim 1, wherein the light-emitting polymer layer is a white-light-emitting polymer layer.

15. A device according to claim 1, wherein the hole transport layer has a thickness between 20 nm and 50 nm.

16. A device according to claim 1, wherein the light-emitting polymer layer has a thickness between 40 nm and 80 nm.

17. A device according to claim 1, wherein the oxide material layer, the hole transport layer and the light-emitting polymer layer have a total thickness between 80 nm and 130 nm.

18. A method of forming an electroluminescent device, comprising the steps of:
a. Providing a semiconducting substrate having a metal anode;
b. Depositing a thermodynamically stable oxide material on the anode;
c. Coating the oxide with a conjugated polymer hole transport layer;
d. Cross linking said hole transport layer;
e. Coating the hole transport layer with a layer of light-emitting polymer;
f. Coating a cathode on the light-emitting polymer; and
g. Encapsulating the device.

19. A method according to claim 18, wherein after step (a) the anode is cleaned to remove native oxide.

20. A method according to claim 18, wherein after step (b) the oxide material is annealed or exposed to plasma.

21. A method according to claim 18, wherein the layer of oxide material is from 1 to 15 nm thick.

22. A method according to claim 18, wherein the hole transport layer has a thickness between 20 nm and 50 nm.

23. A method according to claim 18, wherein the light-emitting polymer layer has a thickness between 40 nm and 80 nm.

24. A method according to claim 18, wherein the oxide material layer, the hole transport layer and the light-emitting polymer layer have a total thickness between 80 nm and 130 nm.
